(19) United States
(12) Patent Application Publication
(10) Pub. No.: US 2025/0212494 A1
(43) Pub. Date: Jun. 26, 2025

(54) Method for Forming a Semiconductor Structure

(71) Applicant: IMEC VZW, Leuven (BE)

(72) Inventors: Serge Biesemans, Leuven (BE); Hans Mertens, Leuven (BE); Boon Teik Chan, Wilsele (BE); Naoto Horiguchi, Leuven (BE); Juergen Boemmels, Heverlee (BE)

(21) Appl. No.: 18/983,750

(22) Filed: Dec. 17, 2024

(30) Foreign Application Priority Data
Dec. 22, 2023 (EP) 23220010.5

(51) Int. Cl. H10D 84/01; H01L 21/02; H01L 21/311; H10D 30/01; H10D 30/43; H10D 30/67; H10D 84/85

(52) U.S. Cl. CPC H10D 84/0181; H01L 21/0214; H01L 21/0228; H01L 21/31116; H10D 30/014; H10D 30/43; H10D 30/6735; H10D 84/0177; H10D 84/0188; H10D 84/851

(57) ABSTRACT

A method for forming a semiconductor structure includes forming a layer stack. The method also includes forming a gate structure on the layer stack, and forming at least one cavity by removing the at least one second sacrificial layer of the layer stack. The method further includes depositing a first dielectric material, and filling the at least one cavity with the first dielectric material. Further, the method includes providing a dielectric free gate surface, free from the first dielectric material. Furthermore, the method includes depositing a second dielectric material on the dielectric free gate surface. The second dielectric material is different from the first dielectric material.

### CROSS-REFERENCE TO RELATED APPLICATIONS

The present application is a non-provisional patent application claiming priority to European Patent Application No. 23220010.5, entitled “A method for forming a semiconductor structure” and filed Dec. 22, 2023, the contents of which are hereby incorporated by reference.

### FIELD OF THE DISCLOSURE

This disclosure relates, in general, to a semiconductor structure. In particular, it relates to a method for forming a semiconductor structure for a field effect transistor or a stack of field effect transistors.

### BACKGROUND

Modern semiconductor integrated circuit technology includes field effect transistors (FETs), for example nanowire FET (NWFET) and nanosheet FET (NSHFET). Further, FETs may be stacked on top of each other to form a stack of FETs. One example is a stack of FETs comprising a complementary pair of FETs stacked on top of each other, e.g., a p-type FET (PFET) on top of a n-type FET (FET), or vice versa. Such a stack of complementary FETs may be referred to as a CFET.

Dielectric material can be used to electrically insulate one part of a FET from another part of the FET or to electrically insulate one FET from another FET

### SUMMARY

This description relates to facilitating semiconductor structures and/or FETs of high quality. This description also relates to semiconductor structures and/or FETs which are densely packed. Furthermore, this description relates to facilitating FETs which are fast and/or operate at high frequencies. Additionally, the description relates to facilitating FETs with low parasitic capacitances.

According to a first aspect, a method for forming a semiconductor structure is provided. The method comprises forming a layer stack on a substrate. The layer stack comprises a first sub-stack comprising a first sacrificial layer, and on the first sacrificial layer a channel layer defining a topmost layer of the first sub-stack. The layer stack also comprises a second sub-stack on the first sub-stack and comprising a plurality of sacrificial layers alternating between first and second sacrificial layers. First sacrificial layers define a respective bottommost and topmost layer of the second sub-stack. The second sub-stack comprises at least one second sacrificial layer. The layer stack further comprises a third sub-stack on the second sub-stack and comprising a channel layer defining a bottommost layer of the third sub-stack and a first sacrificial layer on the channel layer. The first sacrificial layers are formed of a first sacrificial semiconductor material. The second sacrificial layers are formed of a second sacrificial semiconductor material different from the first sacrificial semiconductor material. The method also includes forming a gate structure on the layer stack. The method further includes forming at least one cavity by removing the at least one second sacrificial layer of the second sub-stack. Additionally, the method includes depositing a first dielectric material. Depositing the first dielectric material comprises filling the at least one cavity with the first dielectric material. Further, the method includes providing a dielectric free gate surface. The dielectric free gate surface being an end surface of the gate structure, free from the first dielectric material. Furthermore, the method includes depositing a second dielectric material on the dielectric free gate surface. The second dielectric material is different from the first dielectric material. Depositing the second dielectric material is performed after depositing the first dielectric material.

The term “layer stack” for this description means a structure of layers, sequentially formed on top of each other. As an example, a device layer stack can be fin-shaped.

The first sub-stack designates a first subset of consecutive layers of the layer stack. The second sub-stack designates a second subset of consecutive layers of the layer stack. The third sub-stack designates a third subset of consecutive layers of the layer stack.

The term “a first layer on a second layer,” in reference to any of the layers (or sub-stacks) of the layer stack, means, unless stated otherwise, that the first layer is arranged directly on (i.e. in abutment with) the second layer.

Relative spatial terms such as “topmost,” “bottom,” “lower,” “vertical,” and/or “stacked on top of,” in this description denote locations or directions within a frame of reference of the semiconductor device. In particular, the terms can be understood in relation to a normal direction to the substrate on which the device layer stack is formed, or equivalently in relation to a bottom-up direction of the device layer stack. Correspondingly, terms such as “lateral” and “horizontal” denote locations or directions parallel to the substrate.

The term “thickness” is to be understood as a dimension of a structure (e.g. a layer of a sub-stack) as seen along a normal to a surface underlying the structure (e.g. the layer of the sub-stack). For example, the thickness of a layer of the device layer stack, or the thickness of the second sub-stack, can refer to the thickness dimension of the layer/sub-stack as seen along the bottom-up direction of the device layer.

The semiconductor structure can be a semiconductor structure for producing a stack of field effect transistors (FETs) comprising a top and bottom FET. The stack of FETs can be CFET, wherein the top FET is a NFET and the bottom FET is a PFET, or vice versa. Thus, the semiconductor structure can be a semiconductor structure suitable to be converted into a stack of FETs, e.g. a CFET.

The layer stack can be a layer stack for producing a stack of FETs.

Channel layers of the first sub-stack can be channel layers for a bottom FET. Similarly, channel layers of the third sub-stack can be channel layers for a top FET. Accordingly, channel layers can be channel layers for a FET. Channel layers can be Si layers.

First sacrificial layers can be layers that can be replaced with a gate stack during production of a stack of FETs.

Second sacrificial layers can be layers that are replaced with first dielectric material during production of a stack of FETs. The first dielectric material can then function as electrical isolation between the bottom FET and the top FET. Such electrical isolation between the bottom FET and the top FET can be referred to as middle dielectric isolation.

A material of the channel layers can be Si₁₋ₐGeₐ. The first sacrificial semiconductor material can be Si_{1-c}Ge_{c}. The second sacrificial semiconductor material can be Si_{1-d}Geₐ. The subscripts a, c, and d can, for example, be defined as 0≤a<c<d. In accordance with that example, the subscript “a” can be less than 0.05 (for example, a=0), the subscript “c” can be in a range of 0.1 to 0.25, and the subscript “d” can be in a range of 0.35 to 0.5. For instance, the material of channel layers can be Si, the first sacrificial semiconductor material can be Si_{0.8}Ge_{0.2}, and the second sacrificial semiconductor material can be Si_{0.6}Ge_{0.4}.

The channel layers can include layers of silicon (e.g., as indicated above). The first and third sub-stack can respectively comprise a single channel layer or a plurality of channel layers, e.g. at least two channel layers.

Neighboring channel layers of the first sub-stack can be separated by a first sacrificial layer. Thus, the first sub-stack can comprise a number of repeats of a first sub-stack unit. Each first sub-stack unit can comprise a first sacrificial layer, and a channel layer on the first sacrificial layer. For example, two repeats of the first sub-stack unit can include and/or be arranged as, from bottom to top: first sacrificial layer/channel layer/first sacrificial layer/channel layer.

Neighboring channel layers of the third sub-stack can be separated by a first sacrificial layer. Thus, the third sub-stack can comprise a number of repeats of a third sub-stack unit. Each third sub-stack unit can comprise a channel layer, and a first sacrificial layer on the channel layer. For example, two repeats of the third sub-stack unit can include and/or be arranged as, from bottom to top: channel layer/first sacrificial layer/channel layer/first sacrificial layer.

The semiconductor structure can be seen as extending between two ends. When the stack of FETs is finished, source regions can be arranged at one end and drain regions can be arranged at the other end, in a direction perpendicular to a gate structure.

The second sub-stack can comprise a plurality of sacrificial layers alternating between first and second sacrificial layers. The first sacrificial layers define the respective bottommost and topmost layer of the second sub-stack.

For example, the second sub-stack can comprise a first sacrificial layer as a bottommost layer and a first sacrificial layer as a topmost layer, with a single second sacrificial layer therebetween. This would correspond to a situation where the second sub-stack comprises solely one second sacrificial layer.

As another example, the second sub-stack can, however, comprise a plurality of second sacrificial layers, e.g. at least two second sacrificial layers or at least three second sacrificial layers, each separated by a respective first sacrificial layer. Thus, the method can be configured such that the second sub-stack comprises at least two second sacrificial layers, such that at least two cavities are formed and filled with the first dielectric material.

As an example, a second sub-stack comprising exactly two second sacrificial layers can correspond to the following layer sequence, from bottom to top: first sacrificial layer/second sacrificial layer/first sacrificial layer/second sacrificial layer/first sacrificial layer. A second sub-stack comprising at least two second sacrificial layers can provide good electrical isolation between the top and bottom FET. Some embodiments use a second sub-stack comprising a plurality of thin second sacrificial layers rather than a second sub-stack comprising one thick second sacrificial layer. Lattice mismatch between first and second sacrificial layers may cause dislocations if a thick second sacrificial layer is used.

The plurality of sacrificial layers alternating between first and second sacrificial layers can also be expressed as the plurality of sacrificial layers switching between first and second sacrificial layers.

The gate structure can be a sacrificial gate body. The sacrificial gate body can be replaced by a gate stack later during the production of the stack of FETs. The sacrificial gate body can comprise amorphous silicon. Further, first sacrificial layers can be replaced by the gate stack.

Alternatively, the gate structure can be part of the final gate of the stack of FETs.

As mentioned earlier, the semiconductor structure can be seen as extending between two ends. The layer stack of the semiconductor structure can be fin-shaped. Thus the two ends can be ends of the fin-shaped layer stack. A direction between the two ends of the semiconductor structure can be perpendicular to the gate structure. A direction between the two ends of the semiconductor structure can be parallel to the fin-shaped layer stack. Thus, the gate structure can also have two ends. One end surface of the gate structure can be a surface (e.g. a vertical surface) facing what will become the source region at the end of the production of the stack of FETs. Another end surface of the gate structure can be a surface (e.g. a vertical surface) facing what will become the drain region at the end of the production of the stack of FETs. Accordingly, an end surface of the gate structure can be a surface in a vertical plane.

Removing the at least one second sacrificial layer of the second sub-stack can be performed by selective etching, e.g. etching selectively to the other layers of the layer stack. Thus, the other layers of the layer stack can remain when the at least one second sacrificial layer of the second sub-stack is removed.

Depositing the first dielectric material, to fill the at least one cavity with the first dielectric material, can be performed by various deposition methods. For example, depositing the first dielectric material can be performed by atomic layer deposition (ALD), such as plasma enhanced ALD (PEALD). As another example, depositing the first dielectric material can be performed by chemical vapor deposition (CVD). For example, a first CVD method can be used. The first CVD method is discussed further below.

The dielectric free gate surface can be provided in various ways. The dielectric free gate surface is an end surface of the gate structure, free from the first dielectric material.

A first way of providing a dielectric free gate surface can include removing first dielectric material from the gate surface. As will be described further below, when the first dielectric material is deposited, there can also be first dielectric material deposited on the gate structure. In this case, the dielectric free gate surface can be provided by removing first dielectric material from the end surface of the gate structure.

A second way of providing a dielectric free gate surface can be to deposit first dielectric material by a method which does not deposit on the gate surface. As will be described further below, the first dielectric material can be deposited in the at least one cavity, such that no first dielectric material is deposited on the end surface of the gate structure. For example, the first CVD method can be used to deposit first dielectric material in the at least one cavity.

As mentioned, the second dielectric material is deposited on the dielectric free gate surface. Further, the second dielectric material is different from the first dielectric material. The second dielectric material deposited on the dielectric free gate surface can function as a gate spacer in the finished device.

Depositing the second dielectric material can be performed by atomic layer deposition.

Different dielectric materials within the layer stack and on the end surfaces of the gate structure can be used. Accordingly, in a finished stack of FETs, the middle dielectric isolation can comprise one dielectric material (e.g., a first dielectric material) while the gate spacer comprises another dielectric material (e.g., a second dielectric material). There can be various factors to consider with regards to dielectric material. One factor can be the capacitance between the components separated by the dielectric material. The capacitance can relate to the dielectric constant of the dielectric material. Another factor can be surface states between the dielectric material and the surface on which it is arranged. Another factor can be the amount of voids in the dielectric constant. The factors constraining middle dielectric isolation dielectric material can be different from the factors constraining gate spacer dielectric material. The example embodiments allow the middle dielectric isolation dielectric material and gate spacer dielectric material to be individually tailored.

For example, a gate spacer with low dielectric constant can be used. Accordingly, the second dielectric material can have a low dielectric constant. This can also be expressed as the second dielectric material being low-k material. This can reduce parasitic capacitances. Thereby, FETs which are fast and/or operate at high frequencies are facilitated. Further, the FETs can be more densely packed if the parasitic capacitances are reduced.

As another example, the second dielectric material can have a dielectric constant below 6.5. This can provide low parasitic capacitances. It should be understood that the second dielectric material can have an even lower dielectric constant. Accordingly, the second dielectric material can have a dielectric constant below 6, or below 5.5, or below 5, or below 4.5.

The second dielectric material can comprise SiOCN and/or SiOC. Such materials can have a low dielectric constant. Further, such materials can be hard and durable. The above materials can be deposited e.g. by ALD.

The first dielectric material can, for example, be or comprise SiN, a material very compatible with the production of stacks of FET and for which there are many suitable methods for deposition and etching. Alternatively, the first dielectric material can be or comprise SiOC or SiOCN or SiCN. The above materials can be deposited, for example, by ALD. Alternatively, The above materials can be deposited by the first CVD method.

The first way of providing a dielectric free gate surface is described. The method can be configured such that the first dielectric material is deposited on the end surface of the gate structure when filling the at least one cavity with the first dielectric material.

Even more, forming the dielectric free gate surface comprises removing first dielectric material from the end surface of the gate structure. As an example, removing first dielectric material from the end surface of the gate structure can be performed by dry isotropic etching. Dry isotropic etching allows first dielectric material to be etched at a uniform rate (at least substantially). Further, such etching can also be used for other steps in the process of manufacturing a stack of FETs, for example, during formation of inner spacers. Thus, dry isotropic etching can be easily available.

After removing first dielectric material from the end surface of the gate structure, the second dielectric material can be deposited.

Next, the second way of providing a dielectric free gate surface will be discussed. Herein, the first dielectric material is deposited in the at least one cavity without depositing on the gate surface. A suitable method for doing so is the first CVD method.

Accordingly, the method for forming the semiconductor structure can be configured such that depositing the first dielectric material is performed by a first chemical vapor deposition method (i.e., a first CVD method). The first CVD method comprises reacting, as a film-forming gas, an oxygen-containing silicon compound gas with a non-oxidizing hydrogen-containing gas in a state in which at least the non-oxidizing hydrogen-containing gas is plasmarized, to form a film of a flowable silanol compound; and subsequently, annealing the film of flowable silanol compound into the first dielectric material. The oxygen-containing silicon compound gas comprises Si_{α}O_{β}(O—CₘHₙ)ΓCₓH_{y}. The subscript m, n, and α are integers of 1 or more. The subscript β, Γ, x, and y are integers of 0 or more. β and Γ are not 0 at the same time.

The first CVD method is described in United States Patent Application Publication No. 2022/0235456 A1, entitled “Method for Forming Insulation Film,” and filed May 12, 2020. United States Patent Application Publication No. 2022/0235456 A1 is hereby incorporated by reference in its entirety.

The first CVD method can be called Ultra Chemical Vapor Deposition (UCVD) or Chemical Vapor Liquid Deposition. In the following description the term UCVD will primarily be used.

The UCVD method can deposit material in cavities and/or trenches. For example, the dielectric material can be deposited in the cavity formed by removing the second sacrificial layer. The end surface of the gate structure can be free from first dielectric material after the deposition of first dielectric material.

Additionally, dielectric material deposited by the UCVD method can have a flat profile. It can, in this context, be noted that “flat profiles” generally means that end surfaces of the dielectric material have little or no rounding. The rounding of corners of the end surfaces can sometimes be referred to as curving. The provision of such flat profile dielectric material can enable a reduction of processing steps since separate steps such as pre-cleaning may not be needed. The reduction of pre-cleaning steps can enable a reduction of erosion of the dielectric layers/sacrificial layer, or any other layers of the layer stack that would normally be subjected to erosion. Further, the UCVD method can provide dielectric material compound with few voids, for example, void free dielectric material, and thereby there can be provided high quality dielectric material.

The method can further comprise: removing, by vertical recessing, ends of the layer stack and second dielectric material on the ends; subsequently, laterally recessing end surfaces of the first sacrificial layers of the layer stack to form recesses; and forming inner spacers in the recesses.

The term “inner spacers” means dielectric layer portions formed in the recesses to cover end surfaces of the first sacrificial layers. The vertical recessing can be source/drain recessing. The vertical recessing can be performed by anisotropic etching, for example, dry anisotropic etching. Laterally recessing end surfaces of the first sacrificial layers of the layer stack can be performed by an isotropic etching process. Forming the inner spacers can comprise depositing inner spacer material layer with a thickness such that the recesses are pinched-off (i.e., closed). The inner spacer material can be conformally deposited, for example, by ALD.

The method for forming the semiconductor structure can comprise further steps towards a finished stack of FETs.

For implementations in which the gate structure is a sacrificial gate body, the method can further comprise replacing the sacrificial gate body with a gate stack.

The method can comprise forming source/drain regions at opposite ends of the channel layers of the first sub-stack. The method can also comprise forming source/drain regions at opposite ends of the channel layers of the third sub-stack, such that the semiconductor structure forms a stack of field effect transistors (FETs). The stack of FETs can include a first FET comprising the channel layer of the first sub-stack, and a second FET comprising the channel layer of the second sub-stack.

Liner layers can be used in some embodiments. Thus, the method can be configured such that neighboring first and second sacrificial layers of the second sub-stack are separated by a liner layer. The liner layers of the second sub-stack are formed of a semiconductor material different from the first and second sacrificial semiconductor materials.

The liner layers can include layers resistant to the etchant used to etch the second sacrificial layers. The liner layers can include layers resistant to the etchant used to recess the first sacrificial layers. The liner layers can be thin, for example, thinner than the first and second sacrificial layers.

As mentioned, the first and second sacrificial layers are formed of different semiconductor materials. Thus, etchants can have different etch rates for the first and second sacrificial layers. Thus, the first and second sacrificial layers can be selectively etched at different points in the production process, or should they be etched at the same time, they will be etched a different amount. The channel layers, liner layers, first sacrificial layers and second sacrificial layers can all be of different materials. Alternatively, channel layers and liner layers are formed of the same material, different from the first and second sacrificial semiconductor materials. In some embodiments, channel layers and liner layers are formed of Si and first and second sacrificial layers are formed of SiGe, wherein first and second sacrificial layers have different Ge composition.

Due to the liner layers, rounding of corners of the first sacrificial layers can be avoided, even if the etching of end surfaces of the first sacrificial layers is done isotropically. In other words, the employment of liner layers enables isotropic selective etching while avoiding rounding of corners of the first sacrificial layers. As first sacrificial layers can later be replaced by a gate stack, the use of liner layers can facilitate a well-defined gate stack.

Due to the liner layers, a smaller difference in composition between first and second sacrificial layers can be used than if no liner layers are present. For example, the difference in Ge composition between first and second sacrificial layers can be small when liner layers are used. Even if the etch selectivity is small when the difference in Ge composition is small, the liner layers can help to protect the first sacrificial layers during removal of the second sacrificial layers. A small difference in composition between first and second sacrificial layers can reduce strain related problems, e.g. strain related formation of dislocations.

According to a second aspect, a semiconductor structure is provided. The semiconductor structure comprises a layer stack. The layer stack comprises a first sub-stack including a first sacrificial layer, and on the first sacrificial layer, a channel layer defining a topmost layer of the first sub-stack. The layer stack also comprises a second sub-stack on the first sub-stack. The second sub-stack includes a plurality of layers alternating between first sacrificial layer and layer of first dielectric material. First sacrificial layers define a respective bottommost and topmost layer of the second sub-stack. The layer stack further comprises a third sub-stack on the second sub-stack. The third sub-stack includes a channel layer defining a bottommost layer of the third sub-stack and a first sacrificial layer on the channel layer. The first sacrificial layers are formed of a first sacrificial semiconductor material, a gate structure arranged on the layer stack, and a second dielectric material arranged on an end surface of the gate structure. The second dielectric material is different from the first dielectric material.

A device according to the second aspect can have the same advantages, or similar advantages, as the advantages described in conjunction with the first aspect.

In accordance with the discussion regarding the method of the first aspect, the second dielectric material of the device can have a dielectric constant below 6.5. For example, the second dielectric material can have a dielectric constant below 6, or below 5.5, or below 5, or below 4.5

### BRIEF DESCRIPTION OF THE FIGURES

The above, as well as additional, features will be better understood through the following illustrative and non-limiting detailed description of example embodiments, with reference to the appended drawings. In the drawings like reference numerals will be used for like elements unless stated otherwise.

FIG. 1a, FIG. 1b, FIG. 1c, FIG. 1d, FIG. 1e, FIG. 1f, and FIG. 1g illustrate a method for forming a semiconductor structure, according to an example embodiment.

FIG. 2a and FIG. 2b illustrate further steps towards a finished stack of FETs, according to an example embodiment.

FIG. 3a and FIG. 3b illustrate further steps towards a finished stack of FETs, according to an example embodiment.

FIG. 4a and FIG. 4b illustrate further steps towards a finished stack of FETs, according to an example embodiment.

FIG. 5a and FIG. 5b illustrate further steps towards a finished stack of FETs, according to an example embodiment.

FIG. 6a and FIG. 6b illustrate further steps towards a finished stack of FETs, according to an example embodiment.

FIG. 7a and FIG. 7b illustrate further steps towards a finished stack of FETs, according to an example embodiment.

FIG. 8a, and FIG. 8b illustrate further steps towards a finished stack of FETs, according to an example embodiment.

FIG. 9a, FIG. 9b, and FIG. 9c illustrate the use of liner layers, according to an example embodiment.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

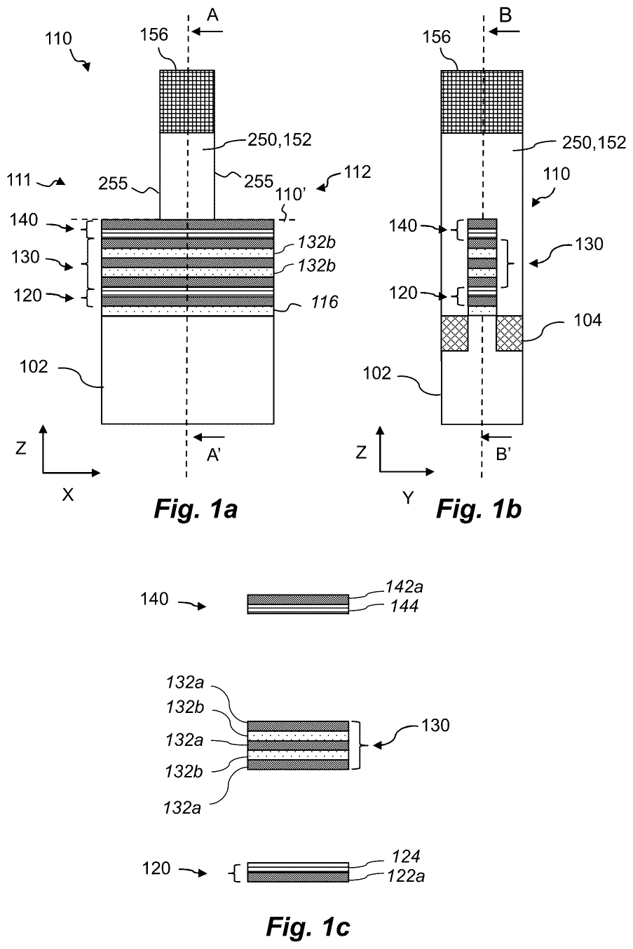

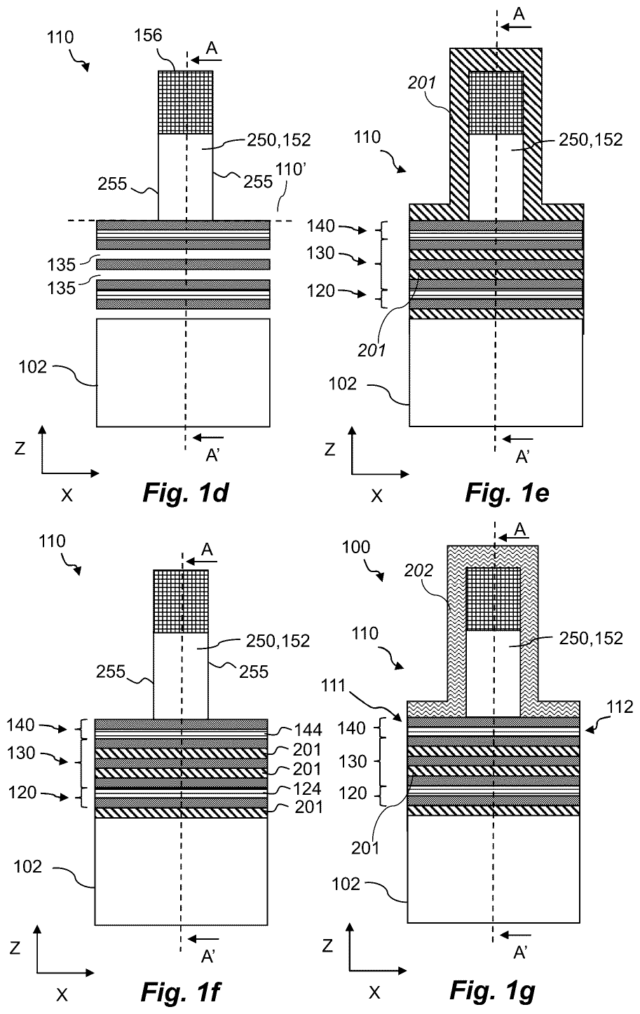

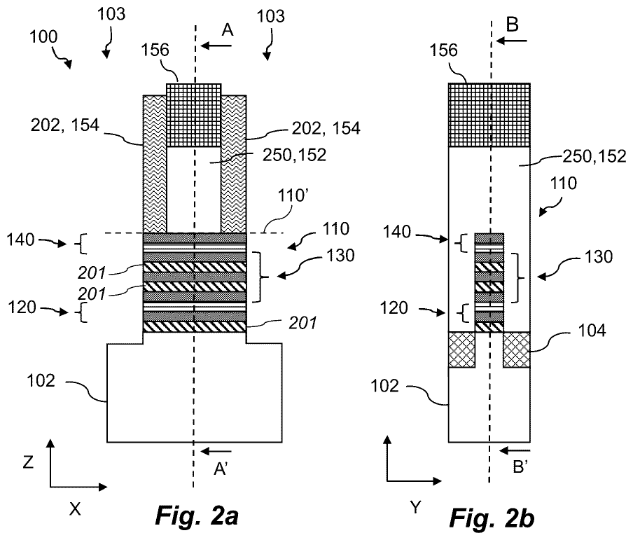

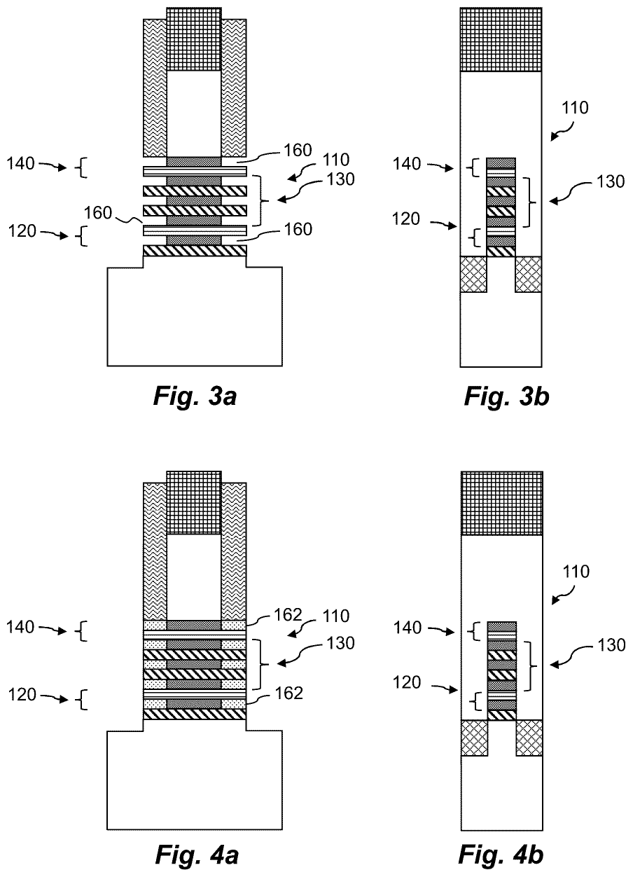

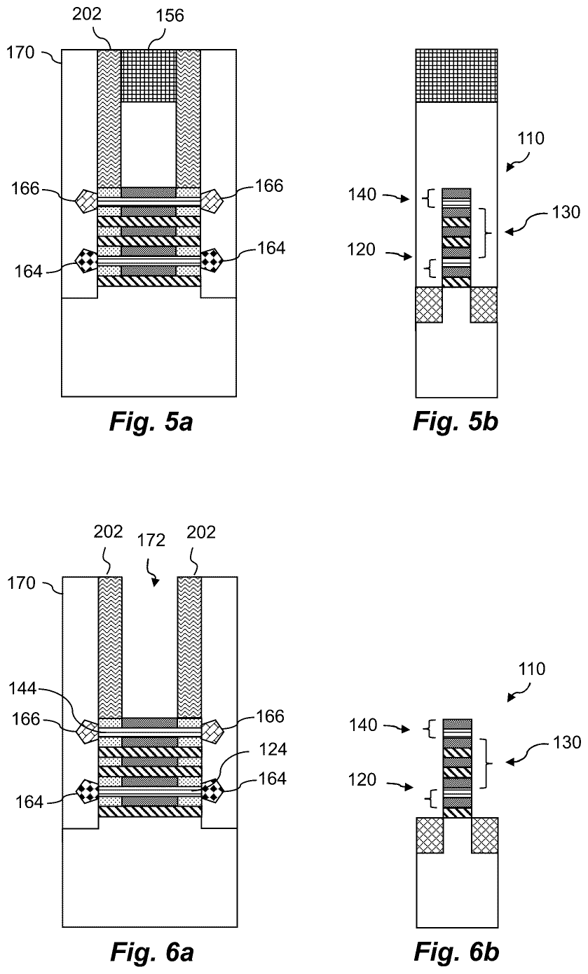

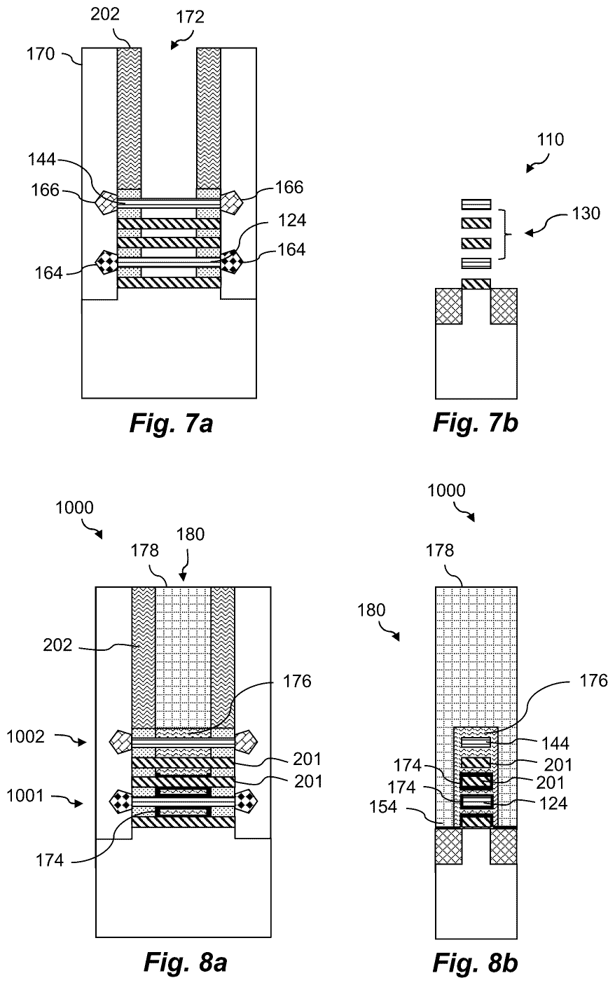

FIG. 1a to FIG. 1g illustrate an example implementation of a method for forming a semiconductor structure. FIG. 2a and FIG. 2b illustrate further steps towards a finished stack of FETs. Likewise, FIG. 3a and FIG. 3b illustrate further steps towards a finished stack of FETs. Similarly, FIG. 4a and FIG. 4b illustrate further steps towards a finished stack of FETs. FIG. 5a and FIG. 5b also illustrate further steps towards a finished stack of FETs. Additionally, FIG. 6a and FIG. 6b illustrate further steps towards a finished stack of FETs. FIG. 7a and FIG. 7b also illustrate further steps towards a finished stack of FETs. Furthermore, FIG. 8a and FIG. 8b illustrate further steps towards a finished stack of FETs.

The axes X, Y and Z (shown in at least some figures) indicate a first direction, a second direction transverse to the first direction, and a vertical or bottom-up direction, respectively. The X-direction and the Y-direction can be referred to as lateral or horizontal directions in that they are parallel to a main plane of a substrate 102 of a structure 100. The Z-direction is parallel to a normal direction to the substrate 102.

FIG. 1a and FIG. 1b depict respective cross-sectional views of a layer stack 110 taken along vertical planes B-B′ (parallel to the XZ-plane) and A-A′ (parallel to the YZ plane). FIG. 1c is a schematic illustration of the first, second, and third sub-stacks. The cross-sectional views of FIG. 1d to FIG. 1g correspond to that of FIG. 1a unless stated otherwise, i.e. along vertical planes B-B′. The layer stack 110 has a first end 111 and a second end 112, as illustrated in FIG. 1a.

The layer stack 110 is arranged on a substrate 102. The substrate 102 can be a conventional semiconductor substrate suitable for complementary FETs. The substrate 102 can be a single-layered semiconductor substrate, for instance formed by a bulk substrate such as a silicon (Si) substrate, a germanium (Ge) substrate or a silicon-germanium (SiGe) substrate. A multi-layered/composite substrate is however also possible, such as an epitaxially grown semiconductor layer on a bulk substrate, or a semiconductor-on-insulator (SOI) substrate, such as a Si-on-insulator substrate, a Ge-on-insulator substrate, or a SiGe-on-insulator substrate.

The layer stack 110 comprises a first sub-stack 120, a second sub-stack 130 on the first sub-stack 120, and a third sub-stack 140 on the second sub-stack 130.

FIG. 1c depicts the first sub-stack 120 (bottom), the second sub-stack 130 (middle) and the third sub-stack 140 (top) in isolation for illustrational clarity.

The first sub-stack 120 comprises a first sacrificial layer 122a and a channel layer 124 on the first sacrificial layer 122a. The channel layer 124 forms a top (i.e. topmost) layer of the first sub-stack 120. The first sacrificial layer 122a and the channel layer 124 can be referred to as one unit of the first sub-stack 120. Although FIG. 1c depicts merely one such unit (i.e. a single unit) of the first sub-stack 120, it is to be understood that the first sub-stack 120 can comprise more than merely a single unit. For instance, the first sub-stack 120 can comprise two, three, four, or more units. As such, the first sub-stack 120 can comprise two, three, four, or more first sacrificial layers 122a and two, three, four, or more channel layers 124. In case the first sub-stack 120 comprises a plurality of such units, the units can be consecutively arranged. For instance, the units can be arranged on top of each other.

The second sub-stack 130 comprises a plurality of sacrificial layers alternating between first and second sacrificial layers 132a, 132b.

FIG. 1c illustrates a second sub-stack 130 comprising (along a bottom-up direction) a bottommost first sacrificial layer 132a, a second sacrificial layer 132b, a first sacrificial layer 132a, a second sacrificial layer 132b, and a topmost first sacrificial layer 132a. The bottommost first sacrificial layer 132 is thus arranged on the first sub-stack 120, i.e. on the channel layer 124. Although FIG. 1c depicts merely two second sacrificial layers 132b of the second sub-stack 130, it is to be understood that the second sub-stack 130 can comprise more than two second sacrificial layers 132b. It is also conceivable that the second sub-stack 130 can comprise one (i.e. a single) second sacrificial layer 132b.

The third sub-stack 140 comprises a channel layer 144 and a first sacrificial layer 142a on the channel layer 144. The channel layer 144 forms a bottom (i.e. bottom-most) layer of the third sub-stack 140. The channel layer 144 is thus arranged on the second sub-stack 130, i.e. on the topmost first sacrificial layer 132a. The channel layer 144 and the first sacrificial layer 142a can be referred to as one unit of the third sub-stack 140. Although FIG. 1c depicts merely one such unit (i.e. a single unit) of the third sub-stack 140, it is to be understood that the third sub-stack 140 can comprise more than merely a single unit. For instance, the third sub-stack 140 can comprise two, three, four, or more. units. As such, the third sub-stack 140 can comprise two, three, four, or more first sacrificial layers 142a and two, three, four, or more channel layers 144. In case the third sub-stack 140 comprises a plurality of such units, the units can be consecutively arranged. For instance, the units can be arranged on top of each other.

The first sacrificial layers 122a, 132a, 142a of the first through third sub-stacks 120, 130, 140, respectively, and the second sacrificial layers of the first through third sub-stacks 120, 130, 140 can be formed with a uniform or at least similar thickness. It is also conceivable that the second sacrificial layers can be formed with a greater thickness than each of the first sacrificial layers 122a, 132a, 142a of the first through third sub-stacks 120, 130, 140, respectively. The total thickness of the second sub-stack 130 can accordingly exceed a thickness of each first sacrificial layer of the first sub-stack 120 and the third sub-stack 140.

The channel layers 124, 144 of the first sub-stack 120 and the third sub-stack 140, respectively, can be of a uniform or at least similar thickness, e.g. a different or a same thickness as the first sacrificial layers of the layer stack 110.

By way of example, the channel layers 124, 144 of the first and third sub-stacks 120, 140, respectively, can each be formed with a thickness of 3-10 nm, the first sacrificial layers 122a, 132a, 142a of the first through third sub-stacks 120, 130, 140, respectively, can each be formed with a thickness of 3-10 nm, the second sacrificial layers 132b can be formed with a thickness of 5-30 nm. The total thickness of the second sub-stack 130 can, for example, be 20-50 nm.

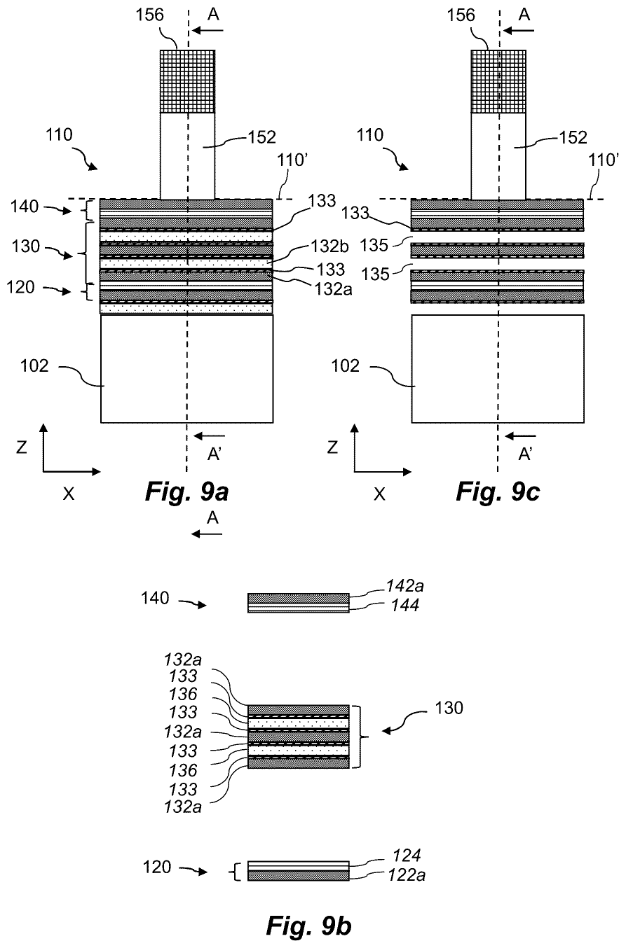

The material of the channel layers (i.e., the channel material) can be Si₁₋ₐGeₐ. The first sacrificial material can be Si_{1-c}Ge_{c}. The second sacrificial material can be Si₁₋ₐGeₐ. The values of the subscripts in those material identifiers can be defined as 0≤a<c<d. For example, the subscript “c” can be in a range of 0.1 to 0.25. As another example, the subscript “d” can be in a range of 0.35 to 0.5. In a more specific example, the channel material can be Si (i.e., a=0), the first sacrificial material can be Si_{0.75}Ge_{0.25}, and the second sacrificial material can be Si_{0.5}Ge_{0.5}. These relative differences in Ge-content facilitate a selective processing (e.g. selective etching) of the different sacrificial layers and the channel layers of the layer stack 110 (and the liner layers discussed in conjunction with FIG. 9a to FIG. 9c).

The layers of the device layer stack 110 can each be epitaxial layers, for example, layers epitaxially grown using deposition techniques, such as chemical vapor deposition (CVD) or physical vapor deposition (PVD). This enables high quality material layers with a degree of control of composition and dimensions.

The deposited layers can be sequentially formed and subsequently patterned to define an elongated fin-shaped layer stack, extending in the X-direction. The dashed line 110′ schematically indicates a contour of the layer stack 110 subsequent to fin patterning and prior to fin recess, described below. While the figures depict only a single layer stack, it is to be understood that a plurality of parallel fin-shaped layer stacks can be formed. Conventional fin patterning techniques can be used, e.g. single patterning techniques such as lithography and etching (“litho-etch”) or multiple-patterning techniques such as (litho-etch) x, self-aligned double or quadruple patterning (SADP or SAQP).

The layers of the layer stack 110 can each be formed as nanosheets, e.g. with a width (along Y) to thickness (along Z) ratio greater than 1, such as a width in a range from 10 nm to 30 nm and a thickness in a range from 3 nm to 10 nm. It is also possible to pattern the layer stacks such that the channel layers form nanowire-shaped layers. A nanowire can, by way of example, have a thickness similar to the example nanosheet however with a smaller width, such as 3 nm to 10 nm.

As shown in FIG. 1a and FIG. 1b, subsequent to the fin patterning, a lower portion of the device layer stack 110 can be surrounded by a shallow trench isolation (STI) 104, e.g., of SiO₂.

As further shown in FIG. 1a and FIG. 1b, a gate structure 250 in the form of a sacrificial gate body 152 can be formed to extend across the layer stack 110. The gate structure 250 comprises two end surfaces 255, as illustrated. The sacrificial gate body 250, 152 can be formed by depositing a sacrificial gate body material (e.g., amorphous Si) over the layer stack 110 and subsequently patterning the sacrificial gate body 250, 152 therein. While the figures depict only a sacrificial gate body 250, 152, it is to be understood that a plurality of parallel sacrificial gate structures can be formed across the layer stack 110. Conventional patterning techniques can be used, e.g., single patterning techniques such as lithography and etching (“litho-etch”) or multiple-patterning techniques such as (litho-etch) x, SADP or SAQP.

On-top of the sacrificial gate body 250, 152 there can be a capping layer 156, for example, formed of one or more layers of hardmask material remaining from the sacrificial gate body patterning.

As shown in FIG. 1a and FIG. 1b, the layer stack 110 can also comprise a bottom second sacrificial layer 116. The bottom second sacrificial layer 116 can be arranged between the substrate 102 and the first sub-stack 120.

The bottom second sacrificial layer 116 can be subject to the same processing steps as the second sacrificial layers 132b of the second sub-stack 130 (and the first sacrificial layers of the first sub-stack 120, the second sub-stack 130, and the third sub-stack 140).

During the manufacturing process for at least some embodiments, the bottom second sacrificial layer 116 can be replaced with dielectric material, for example, replaced with first dielectric material 201, as will be shown later. The dielectric material replacing the bottom second sacrificial layer 116 can form a bottom dielectric isolation for the finished stack of FETs. During the manufacturing process for at least some other embodiments, the bottom second sacrificial layer 116 is not replaced with dielectric material, e.g., is not replaced with first dielectric material 201. Accordingly, a bottom dielectric isolation is not used in some embodiments, and a bottom second sacrificial layer 116 not used in some other embodiments.

FIG. 1d shows the removal of the second sacrificial layers 132b of the second sub-stack 130. In FIG. 1d, the second sacrificial layers 132b of the second sub-stack 130 have been removed by selectively etching the second sacrificial semiconductor material, thereby forming cavities 135 in the second sub-stack 130. The second sacrificial semiconductor material can be etched using an isotropic etching process (wet or dry), to laterally etch back end surfaces of the second sacrificial layers 132b from opposite ends of the layer stack 110. For example, an HCl-based dry etch can be used to remove second sacrificial layer material, e.g., remove second sacrificial material having higher Ge-content than the first sacrificial material. However, other appropriate etching processes (e.g. wet etching processes) are also known in the art and can also be employed for this purpose.

After forming the cavities 135, first dielectric material 201 is deposited to fill the cavities 135. First dielectric material 201 having a dielectric constant below 6.5 can be used. The first dielectric material 201 can be or comprise, for example, SiN, or SiOC, or SiOCN, or SiCN.

The first dielectric material 201 can be deposited to fill the cavities 135 and also cover end surfaces 255 of the gate structure 250, as illustrated in FIG. 1e. In this case, the dielectric free gate surface can be provided by removing first dielectric material 201 from the end surfaces 255 of the gate structure 250, as illustrated in FIG. 1f. This corresponds to the first way of providing a dielectric free gate surface, discussed above.

Alternatively, the first dielectric material 201 can be deposited by a method which does not deposit on the end surfaces 255 of the gate structure 250. In such a case, the situation illustrated in FIG. 1e may not arise. Instead, the layer stack 110 can look as illustrated in FIG. 1f directly after deposition of the first dielectric material 201, without any need for removing first dielectric material 201 from the end surfaces 255 of the gate structure 250. This corresponds to the second way of providing a dielectric free gate surface, discussed above.

In the first way of providing a dielectric free gate surface, the first dielectric material 201 can be deposited by a conformal deposition method, such as ALD. Alternatively, the first dielectric material 201 can be deposited by the first CVD method discussed below.

In the second way of providing a dielectric free gate surface, the first dielectric material 201 can be deposited by a deposition method configured to deposit in cavities 135. Such deposition method can be referred to as a first CVD method.

The first CVD method can comprise reacting, as a film-forming gas, an oxygen-containing silicon compound gas with a non-oxidizing hydrogen-containing gas in a state in which at least the non-oxidizing hydrogen-containing gas is plasmarized, to form a film of a flowable silanol compound, and subsequently, annealing the film of the flowable silanol compound into the first dielectric material. The oxygen-containing silicon compound gas can comprise Si_{α}O_{β}(O—CₘHₙ)ΓCₓH_{y}. The subscripts m, n, and α are integers of 1 or more. The subscripts β, Γ, x, and y are integers of 0 or more. The subscripts β and Γ are not 0 at the same time.

If first dielectric material 201 has been deposited on the end surfaces 255 of the gate structure 250, it can be removed by etching. For example, any suitable isotropic etching process (wet or dry) for etching the dielectric material (e.g. SiN) can be used.

FIG. 1g illustrates a second dielectric material 202 being deposited on the dielectric free gate surface. The second dielectric material 202 is herein different from the first dielectric material 201. The second dielectric material 202 can be deposited by a conformal deposition method, such as ALD. The second dielectric material 202 can comprise SiOCN and/or SiOC. The second dielectric material 202 can, as illustrated, also cover ends 111, 112 of the layer stack 110.

Next, further steps that can be performed to obtain a finished stack of FETs will be discussed, in conjunction with FIG. 2a to FIG. 8b. FIG. 2a and FIG. 2b depict respective cross-sectional views of the layer stack 110 taken along vertical planes B-B′ (parallel to the XZ-plane) and A-A′ (parallel to the YZ plane). The cross-sectional views of the subsequent figures correspond to those in FIG. 2a and FIG. 2b unless stated otherwise.

FIG. 2a and FIG. 2b illustrate that ends 111, 112 of the layer stack 110 can be removed by vertical recessing. Thus, vertical recesses 103 are formed, and these vertical recesses can be called source/drain recesses 103. The vertical recessing can be performed by anisotropic etching, such as dry anisotropic etching. The second dielectric material 202 covering ends 111, 112 of the layer stack 110 can, as illustrated, also be removed by the vertical recessing.

FIG. 3a and FIG. 3b show that subsequent to forming source/drain recesses 103, end surfaces of the first sacrificial layers 122a, 132a, 142a of the layer stack 110 can be laterally recessed to form recesses 160.

In FIG. 3a, recesses 160 have been formed in the layer stack 110 by laterally etching back (e.g., along the X-direction and the negative X-direction) end surfaces of each first sacrificial layer of the layer stack 110 from opposite ends of the layer stack 110, by selective etching. The lateral etch back can be achieved by an isotropic etching process. Any suitable dry etching process or wet etching process allowing selective etching of the first sacrificial material can be used (e.g. HCl, or APM). As indicated in FIG. 3a, the extent of the lateral etch back can correspond to a thickness of the first dielectric material 201 on the respective end surfaces 255 of the gate structure 250.

In FIG. 4a and FIG. 4b, the recesses 160 have been filled with one or more conformally deposited inner spacer materials. Examples of inner spacer materials include conformally deposited dielectric materials, such as an oxide, a nitride or a carbide. In one example, a single inner spacer material (e.g., SiN) can be deposited to fill the recesses 160. In another example, a first inner spacer material (e.g. SiOC) can be deposited to partially fill the recesses 160, and a second inner spacer material (e.g. SiN) can be deposited to fill (by pinch-off) a remaining space in the recesses 160. The inner spacers 162 have been formed in the recesses 160 by subjecting the inner spacer material to an isotropic etching process to remove portions of the inner spacer material deposited outside the recesses 160. Any suitable isotropic etching process (wet or dry) for etching the dielectric material (e.g., SiN or SiN and SiOC) can be used. As shown, the etching can be stopped when end surfaces of the channel layers of the device layer stack 110 are exposed and discrete portions of the inner spacer material remain in the recesses 160 to form the inner spacers 162.

In FIG. 5a and FIG. 5b, source and drain regions 164 and 166 have been formed on the channel layers of the first sub-stack 120 and the third sub-stack 140, respectively. The source and drain regions 164, 166 have been formed by epitaxially growing semiconductor material on end surfaces of the channel layers exposed at opposite ends of the channel layers.

The source and drain regions 164 formed on the channel layer end surfaces of the first sub-stack 120 can be of a first conductivity type and the source and drain regions 166 formed on the channel layer end surfaces of the third sub-stack 140 can be of a second opposite conductive type. The first and second conductivity types can be a p-type and an n-type, or vice versa. The doping can be achieved by in-situ doping. Different conductivity types of the source and drain regions 164 and the source and drain regions 166 can be achieved by masking the channel layer end surfaces of the third sub-stack 140 while performing epitaxy on the channel layer end surfaces of the first sub-stack 120. The masking of the channel layer end surfaces of the third sub-stack can, for example, be provided by forming a temporary cover spacer along the third sub-stack. After completing the epitaxy of the source and drain regions 164, the temporary cover spacer can be removed and the source and drain regions 164 can be covered with one or more dielectric materials (e.g. ALD-deposited SiN and an inter-layer dielectric like SiO₂). Epitaxy can then be performed on the channel layer end surfaces of the third sub-stack 140. This, however, is merely one example and other process techniques facilitating forming of the source and drain regions 164, 166 with different conductivity types can also be used instead or in addition to.

The source and drain regions 164, 166 can, as shown, subsequently be embedded in, or, encapsulated by an insulating layer 170. The insulating layer 170 can be formed of an insulating material, such as an oxide, e.g., SiO₂, or another inter-layer dielectric, deposited, planarized and recessed, e.g., by chemical mechanical polishing (CMP) and/or etch back. The CMP and/or etch back can proceed to also remove any capping layer 156 of the sacrificial gate structure 150. It is also possible, however, to stop the CMP and/or etch back on the capping layer 156 and subsequently open the capping using a separate etch step.

In FIG. 6a and FIG. 6b, a gate trench 172 has been formed by removing the sacrificial gate body 250, 152 between the opposite second dielectric material 202. Any conventional suitable etching process (isotropic or anisotropic, wet or dry) allowing selective removal of the sacrificial gate body 250, 152 (e.g., of amorphous Si) can be used.

In FIG. 7a and FIG. 7b, the first sacrificial layers of the device layer stack 110 have been removed by selectively etching the first sacrificial semiconductor material from the gate trench 172. A same type of etching process can be used for this step as during the forming of the recesses 160. By removing the first sacrificial layers, the channel layers of the device layer stack 110 can be released in the sense that upper and lower surfaces thereof can be exposed within the gate trench 172.

In FIG. 8a and FIG. 8b, a gate stack 180 has replaced the sacrificial gate body 152 and the first sacrificial layers.

The gate stack 180 comprises a gate dielectric layer (not shown), one or more work function metals (WFMs), and gate fill metal 178. In the following example, a gate stack 180 comprising first 174 and second 176 WFMs will be described. At least two WFMs may be needed for a stack of FETs 1000 comprising both an NFET and a PFET. FIG. 8a and FIG. 8b illustrate a stack of FETs 1000 comprising a first FET 1001 and a second FET 1002. In the illustration, one of the first FET 1001 and the second FET 1002 is an NFET and the other is a PFET. Thus, the stack of FETs 1000 forms a CFET.

The gate dielectric layer can be conformally deposited in the gate trench 172 to conformally coat the channel layers. The gate dielectric layer can be formed of a conventional a high-k dielectric, such as HfO₂, HfSiO, LaO, AlO, or ZrO.

Subsequently, the first WFM 174 can be conformally deposited in the gate trench 172. The first WFM 174 can be formed of one or more effective WFMs (e.g., an n-type WFM such as TiAl or TiAlC, and/or a p-type WFM, such as TiN or TaN). The first WFM 174 can thus surround the channel layers of the first sub-stack 120.

Subsequently, the first WFM 174 can be removed from the channel layers of the third sub-stack 140, e.g., using a block mask as an etch mask. The first WFM 174 surrounding the channel layers of the first sub-stack 120 can remain. The second WFM 176 can then be deposited on the gate dielectric surrounding the channel layers of the third sub-stack 140, and on portions of the first dielectric material 201. The second WFM 176 can thus surround the channel layers of the third sub-stack 140. The second WFM 176 can further surround the first WFM 174 of the first sub-stack 120.

The gate dielectric layer and/or the first WFM 174 and/or the second WFM 176 can be conformally deposited, e.g., by ALD.

Subsequently, a gate fill metal 178 (such as W, or Al) can be deposited to fill a remaining space of the gate trench 172. The gate fill metal 176 can, for instance, be deposited by CVD or PVD.

In the discussion above, a layer stack 110 without liner layers 133 has been used. However, liner layers 133 can be used in some embodiments. Accordingly, neighboring first and second sacrificial layers 132a, 132b of the second sub-stack 130 can be separated by a liner layer 133, the liner layers 133 of the second sub-stack 130 being formed of a semiconductor material different from the first 201 and second 202 sacrificial semiconductor materials.

FIG. 9a, FIG. 9b, and FIG. 9c illustrate the principle of liner layers 133.

First, FIG. 9a depicts a cross-sectional view of a layer stack 110 comprising liner layers 133. The layer stack 110 comprises a first sub-stack 120, a second sub-stack 130 on the first sub-stack 120, and a third sub-stack 140 on the second sub-stack 130. The first sub-stack 120 and the third sub-stack 140 can be described analogously to the first sub-stack 120 and third sub-stack 140 discussed in conjunction with FIG. 1a. The second sub-stack 130 can be described analogously to the second sub-stack 130 discussed in conjunction with FIG. 1a, but with the addition of liner layers 133 between neighboring first 132a and second 132b sacrificial layers of the second sub-stack 130. Each liner layer 133 can abut the respective first sacrificial layer 132a and second sacrificial layers 132b that it separates.

Next, FIG. 9b depicts the first sub-stack 120 (bottom), the second sub-stack 130 (middle) and the third sub-stack 140 (top) in isolation for illustrational clarity.

As mentioned, the liner layers 133 are formed of a semiconductor material different from the first and second semiconductor materials. For example, the channel material can be Si₁₋ₐGeₐ, the liner material can be Si_{1-b}Ge_{b}, the first sacrificial material can be Si_{1-c}Ge_{c}, and the second sacrificial material can be Si_{1-d}Geₐ, wherein 0≤a≤b<c<d. For example, b can be in a range of 0-0.05. Further, c can be in a range of 0.1-0.25. Further, d can be in a range of 0.35-0.5. In a more specific example, the channel material can be Si (i.e., a=0), the liner material can be Si (i.e., b=0), the first sacrificial material can be Si_{0.75}Ge_{0.25}, and the second sacrificial material can be Si_{0.5}Ge_{0.5}. These relative differences in Ge-content facilitate a selective processing (e.g., selective etching) of the different sacrificial layers, the liner layers 133, and the channel layers of the layer stack 110.

Liner layers 133 can be formed by epitaxial growth. Liner layers 133 can be formed with a thickness of 1-5 nm.

Next, FIG. 9c depicts a cross-sectional view of the layer stack 110 comprising liner layers 133 after removal of the second sacrificial layers 132b of the second sub-stack 130.

As further shown in FIG. 9c, the liner layers 133 can prevent rounding of the corners of the first sacrificial layers 132a of the second sub-stack 130. As the second sacrificial layers 132b of the second sub-stack 130 are etched, the etchant cannot attack the first sacrificial layers 132a via the cavities 135 formed due to the protective liner layers 133. Thus, the first sacrificial layers 132a of the second sub-stack 130 can only be attacked laterally via the recesses 160 of the second sub-stack 130.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method for forming a semiconductor structure, the method comprising:
forming a layer stack on a substrate, the layer stack comprising:
a first sub-stack comprising a first sacrificial layer, and on the first sacrificial layer, a channel layer defining a topmost layer of the first sub-stack,
a second sub-stack on the first sub-stack and comprising a plurality of sacrificial layers alternating between first and second sacrificial layers, wherein the first sacrificial layers define a respective bottommost and topmost layer of the second sub-stack, and the second sub-stack comprises at least one second sacrificial layer, and
a third sub-stack on the second sub-stack and comprising a channel layer defining a bottommost layer of the third sub-stack and a first sacrificial layer on the channel layer, wherein the first sacrificial layers are formed of a first sacrificial semiconductor material, and the second sacrificial layers are formed of a second sacrificial semiconductor material different from the first sacrificial semiconductor material,
forming a gate structure on the layer stack;
forming at least one cavity by removing the at least one second sacrificial layer of the second sub-stack;
depositing a first dielectric material, wherein depositing the first dielectric material comprises filling the at least one cavity with the first dielectric material;
providing a dielectric free gate surface, the dielectric free gate surface being an end surface of the gate structure, free from the first dielectric material; and
depositing a second dielectric material on the dielectric free gate surface, wherein:
the second dielectric material is different from the first dielectric material, and
depositing the second dielectric material is performed after depositing the first dielectric material.

2. The method according to claim 1, wherein the second dielectric material has a dielectric constant below 6.5.

3. The method according to claim 1, wherein the second dielectric material comprises SiOCN and/or SiOC.

4. The method according to claim 1, wherein the first dielectric material is SiN, or SiOC or SiOCN or SiCN.

5. The method according to claim 1, wherein:
first dielectric material is deposited on the end surface of the gate structure while filling the at least one cavity with the first dielectric material, and
forming the dielectric free gate surface comprises removing first dielectric material from the end surface of the gate structure.

6. The method according to claim 5, wherein removing first dielectric material from the end surface of the gate structure is performed by dry isotropic etching.

7. The method according to claim 1, wherein depositing the first dielectric material is performed by chemical vapor deposition or physical vapor deposition.

8. The method according to claim 1, wherein:
depositing the first dielectric material is performed by a chemical vapor deposition method comprising:
reacting, as a film-forming gas, an oxygen-containing silicon compound gas with a non-oxidizing hydrogen-containing gas in a state in which at least the non-oxidizing hydrogen-containing gas is plasmarized, to form a film of a flowable silanol compound, and
subsequently, annealing the film of the flowable silanol compound into the first dielectric material,
the oxygen-containing silicon compound gas comprises Si_{α}O_{β}(O—CₘHₙ)ΓCₓH_{y},
m, n, and α are integers of 1 or more, and
β, Γ, x, and y are integers of 0 or more; and β and Γ are not 0 at a same time.

9. The method according to claim 1, wherein depositing the second dielectric material is performed by atomic layer deposition.

10. The method according to claim 1, wherein depositing the first dielectric material is performed by conformal deposition.

11. The method according to claim 1, further comprising:
removing, by vertical recessing, ends of the layer stack and second dielectric material on the ends;
subsequently, laterally recessing end surfaces of the first sacrificial layers of the layer stack to form recesses; and
forming inner spacers in the recesses.

12. The method according to claim 1, wherein the second sub-stack comprises at least two second sacrificial layers, such that at least two cavities are formed and filled with the first dielectric material.

13. The method according to claim 1, wherein:
the gate structure is a sacrificial gate body, and
the method further comprises replacing the sacrificial gate body with a gate stack.

14. The method according to claim 13, further comprising:
forming source/drain regions at opposite ends of the channel layer of the first sub-stack; and
forming source/drain regions at opposite ends of the channel layer of the third sub-stack,
wherein the semiconductor structure forms a stack of field effect transistors comprising:
a first field effect transistor comprising the channel layer of the first sub-stack, and
a second field effect transistor comprising the channel layer of the second sub-stack.

15. The method according to claim 1, wherein:
the gate structure comprises a first end surface for forming a source region at an end of a stack of field effect transistors formed by the semiconductor structure, and
the gate structure comprises a second end surface for forming a drain region at the end of the stack of field effect transistors formed by the semiconductor structure.

16. The method according to claim 1, wherein neighboring first and second sacrificial layers of the second sub-stack are separated by a liner layer, the liner layer of the second sub-stack being formed of a semiconductor material different from the first and second sacrificial semiconductor materials.

17. The method according to claim 16, wherein the channel layer defining the topmost layer of the first sub-stack and the channel layer defining the bottommost layer of the third sub-stack are formed from the same material used to form the liner layer of the second sub-stack.

18. The method according to claim 1, wherein:
the channel layer defining the topmost layer of the first sub-stack and the channel layer defining the bottommost layer of the third sub-stack are formed of silicon, and
the first sacrificial semiconductor material and the second sacrificial semiconductor material are formed of SiGe having different Ge compositions.

19. A semiconductor structure comprising:
a layer stack comprising:
a first sub-stack comprising a first sacrificial layer, and on the first sacrificial layer, a channel layer defining a topmost layer of the first sub-stack,
a second sub-stack on the first sub-stack and comprising a plurality of layers alternating between first sacrificial layers and layer of first dielectric material, wherein the first sacrificial layers define a respective bottommost and topmost layer of the second sub-stack, and
a third sub-stack on the second sub-stack and comprising a channel layer defining a bottommost layer of the third sub-stack and a first sacrificial layer on the channel layer, wherein the first sacrificial layers are formed of a first sacrificial semiconductor material;
a gate structure arranged on the layer stack; and
a second dielectric material arranged on an end surface of the gate structure, wherein the second dielectric material is different from the first dielectric material.

20. The semiconductor structure according to claim 19, wherein the second dielectric material has a dielectric constant below 6.5.
